(19) United States
(12) Patent Application Publication
(10) Pub. No.: US 2014/0210568 A1
(43) Pub. Date: Jul. 31, 2014

(54) MATCHING NETWORK

(71) Applicant: Krohne AG, Basel (DE)

(72) Inventor: Arie Huijzer, Sliedrecht (NL)

(73) Assignee: Krohne AG, Basel (DE)

(21) Appl. No.: 14/165,977

(22) Filed: Jan. 28, 2014

(30) Foreign Application Priority Data
Jan. 28, 2013 (DE) 10 2013 001 353.4

(51) Int. Cl. H03H 11/30

(52) U.S. Cl. CPC H03H 11/30
USPC 333/32

(57) ABSTRACT

A matching network for matching the impedance of a load to an impedance of an electrical energy source has an output, an input, an inductance, a capacitance, and a series connection of a nonlinear impedance and the inductance or the capacitance. The series connection is connected in parallel to the output or parallel to the input.

### BACKGROUND OF THE INVENTION

1. Field of the Invention

The invention relates to a matching network for matching the impedance of a load to the impedance of an electrical voltage source or current source or an electrical energy source, with an inductance and a capacitance.

2. Description of Related Art

Often, either an electrical voltage source or an electrical current source is addressed. However, generally, an electrical energy source is meant because generally an electrical voltage source will also make available an electrical current and an electrical current source only makes sense when it also makes available an electrical voltage. (It cannot be denied that there are also electrical voltage sources which need not deliver electrical current; but, electrical voltage sources of this type are not at issue here).

It is generally known that an electrical energy source can deliver or supply a maximum of electrical energy when the impedance of a connected load corresponds to the impedance of the electrical energy source.

Since, in general, the impedance of a load which is connected to an electrical voltage source is not identical to the impedance of this electrical energy source, matching networks are used which provide for the electrical energy source “seeing” as a load an impedance which corresponds to the impedance of the electrical energy source. The formulation that the electrical energy source “sees” as a load the impedance which corresponds to the impedance of the electrical energy source means the following:

Strictly speaking, a matching network of the type under consideration here cannot change the impedance of the load, and therefore, cannot match the impedance of the load to the impedance of an electrical voltage source either. Rather, for the indicated use of a matching network, the matching network, on the one hand, is connected to the electrical energy source, and on the other, to the load. The formulation that the electrical energy source “sees” an impedance as a load therefore means that the matching network for the electrical energy source constitutes an impedance which corresponds to the impedance of the electrical energy source.

Often, the matching networks of the above addressed type have an inductance and a capacitance for matching the impedance of a load to the impedance of an electrical energy source. This matching network will also be assumed below even if other matching networks are known, or can also be imagined, which do what was explained above.

Considerations in conjunction with matching networks which are to be used in ultrasonic transducers will be described below.

Ultrasonic transducers, as an important part of an ultrasonic flow meter, as an important function element have a transducer element, often a piezoelement which is made for sending or receiving ultrasonic waves. If the transducer element is to be used to send ultrasonic waves, an electrical energy source is necessary which supplies the transducer element with electrical energy. If the transducer element is used for receiving ultrasonic waves, generally an electrical amplifier is connected downstream of the transducer element. The first case is hereinafter called the “transmit situation”, the second case the “receive situation”.

A matching network is a quadripole. When used in conjunction with an ultrasonic transducer it must be distinguished between the situation in which the ultrasonic transducer is to send ultrasonic waves (“transmit situation”), and the situation in which the ultrasonic transducer is to receive ultrasonic waves (“receive situation”). For the “transmit situation” the matching network must be connected, on the one hand, to the electrical energy source, and on the other hand, to the transducer element of the ultrasonic transducer. Conversely, for the “receive situation” the matching network must be connected, on the one hand, to the transducer element of the ultrasonic transducer, and on the other, to an amplifier. If the above described matching network under discussion is used in conjunction with an ultrasonic transducer, it is established that what is intended is achieved in the situation in which the ultrasonic transducer sends ultrasonic waves (“transmit situation”), but does not do what it is designed to do when the ultrasonic transducer is to receive ultrasonic waves (“receive situation”).

### SUMMARY OF THE INVENTION

The above addressed problem is solved in accordance with the invention by a series connection of a nonlinear impedance and of the inductance or the capacitance being connected in parallel to the output of the matching network in the initially described matching network.

### BRIEF DESCRIPTION OF THE DRAWINGS

FIG. 1 shows a matching network for matching the impedance of a load to the impedance of an electrical energy source in accordance with the prior art, and

FIG. 2 shows a matching network in accordance with the invention.

### DETAILED DESCRIPTION OF THE INVENTION

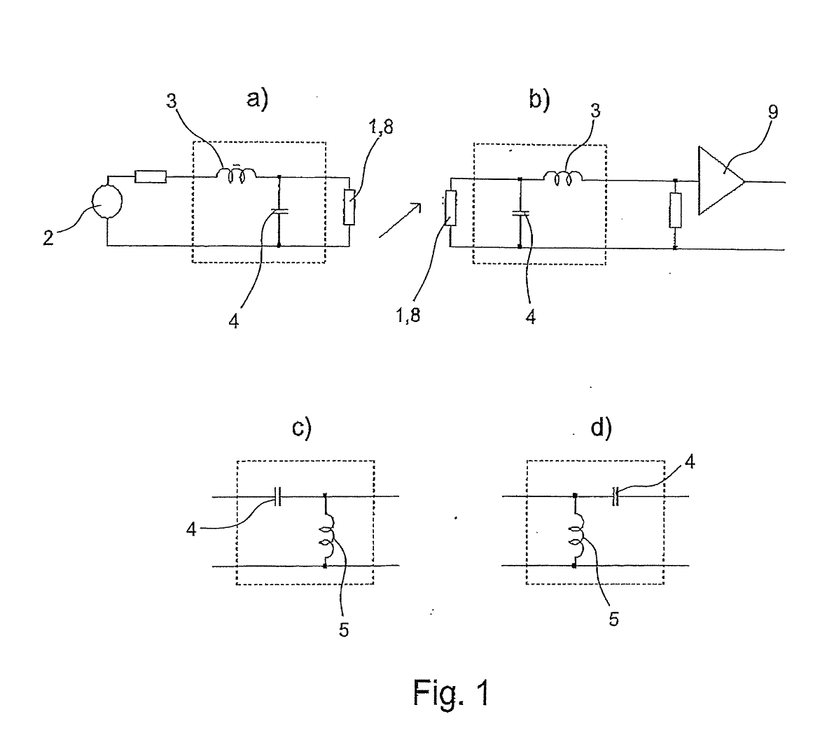

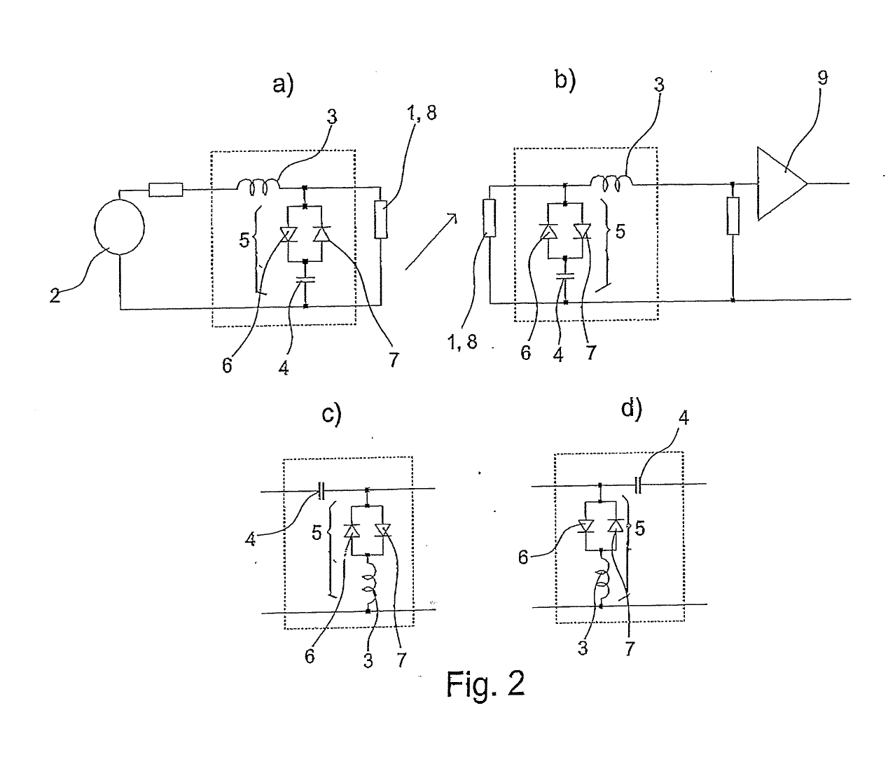

FIG. 1 shows a matching network for matching the impedance 8 of a load 1 to the impedance of an electrical energy source 2. In its fundamental structure the described matching networks, both the one in FIG. 1 and the one in FIG. 2, have an inductance 3 and a capacitance 4. Both in FIG. 1 and also in FIG. 2, parts (a) and (c) show matching networks for the “transmit situation”, while the parts (b) and (d) show matching networks for the “receive situation”.

In accordance with the invention, as FIG. 2 shows, a series connection 5 of a nonlinear impedance and of the inductance or the capacitance is connected parallel to the output of the matching network, sketches (a) and (c), “transmit situation”, or parallel to the input of the matching network, sketches (b) and (d), “receive situation”. In the exemplary embodiment two anti-parallel connected diodes 6, 7 are provided as the nonlinear impedance.

The matching networks in accordance with the invention which are shown in FIG. 2 work normally in the “transmit situation”, when the voltage of the electrical energy source 2 is large enough, the anti-parallel connected diodes 6, 7 are therefore conductive. In the “receive situation,” the illustrated matching networks essentially does not work when the input voltage is so small that the anti-parallel connected diodes 6, 7 are not conducting. This “receive situation” prevails when the transducer element of an ultrasonic transducer is provided as the load 1.

Otherwise sketches (b) in FIGS. 1 and 2 show another amplifier 9 provided for the “receive situation”.

What is claimed is:

1. A matching network for matching the impedance of a load to an impedance of an electrical energy source, comprising:
an output,
an input,
an inductance,
a capacitance,
a series connection of a nonlinear impedance and of the inductance or the capacitance,
wherein the series connection is connected in parallel to the output or in parallel to the input.

2. The matching network in accordance with claim 1, wherein said nonlinear impedance comprises two anti-parallel connected diodes.
